(19) United States
(12) Patent Application Publication
(10) Pub. No.: US 2024/0170365 A1
(43) Pub. Date: May 23, 2024

(54) HEAT-DISSIPATING STRUCTURE FOR ELECTRONIC DEVICE

(71) Applicants: NEC Corporation, Minato-ku, Tokyo (JP); NEC Platforms, Ltd., Kawasaki-shi, Kanagawa (JP)

(72) Inventor: Ayumu Iseda, Kanagawa (JP)

(73) Assignees: NEC Corporation, Minato-ku, Tokyo (JP); NEC Platforms, Ltd., Kawasaki-shi, Kanagawa (JP)

(21) Appl. No.: 18/281,672

(22) PCT Filed: Jan. 17, 2022
(86) PCT No.: PCT/JP2022/001280

§ 371 Date: Sep. 12, 2023

(30) Foreign Application Priority Data
Mar. 18, 2021 (JP) 2021044791

(51) Int. Cl. H01L 23/427

(52) U.S. Cl. CPC H01L 23/427

(57) ABSTRACT

Provided is a heat-dissipating structure having a heat-dissipating path that enables efficient dissipation of heat. An electronic device (100) comprises: a substrate (1); a heat-generating component (2) mounted on the substrate (1); a case (3) attached to the substrate (1) and having a shape at least partially covering the heat-generating component (2); and a heat-dissipating member (4) thermally connected to the case (3). The substrate (1) has a filled-via group (12). The filled-via group (12) is disposed across: a first region (A1) including a region in which the heat-generating component (2) contacts the substrate (1); a second region (A2) including a region in which the case (3) contacts the substrate (1); and a third region (A3) including a region between the first region (A1) and the second region (A2). The filled-via group (12) forms a heat-dissipating path from the heat-generating component (2) to the case (3).

### TECHNICAL FIELD

The present disclosure relates to a heat-dissipating structure for an electronic device.

### BACKGROUND ART

PTL 1 discloses a heat-dissipating structure for a semiconductor module mounted on a multilayer substrate. Specifically, a semiconductor module is mounted on a multilayer substrate, and the semiconductor module and the multilayer substrate are accommodated in an enclosure component, in the technology described in PTL 1. The enclosure component is attached to the multilayer substrate. A surface heat transfer body and an inner-layer heat transfer body are provided on or in the multilayer substrate, and the surface heat transfer body and the inner-layer heat transfer body are connected by a via. A heat-dissipating path from the semiconductor module to the enclosure component is formed by the surface heat transfer body, the inner-layer heat transfer body, and the via (for example, see claim 1 and FIG. 1 in PTL 1).

### CITATION LIST

### Patent Literature

PTL 1: Japanese Unexamined Patent Application Publication No. 2019-096746

### SUMMARY OF INVENTION

### Technical Problem

In the technology described in PTL 1, the surface heat transfer body and the inner-layer heat transfer body are included in the heat-dissipating path from the semiconductor module to the enclosure component. The heat transfer bodies are respectively provided in layers in the multilayer substrate and are thinly shaped. It is difficult to increase the cross-sectional area of the heat-dissipating path particularly in a stacking direction in the multilayer substrate due to such thinly shaped heat transfer bodies being included in the heat-dissipating path. As a result, there is an issue that achievement of efficient heat dissipation is difficult.

An object of the present disclosure is to, in view of the aforementioned issue, provide a heat-dissipating structure including a heat-dissipating path enabling efficient heat dissipation.

### Solution to Problem

A heat-dissipating structure for an electronic device according to an aspect of the present disclosure includes: a substrate; a heat-generating component mounted on the substrate; a case being attached to the substrate and having a shape at least partially covering the heat-generating component; and a heat-dissipating member thermally connected to the case, wherein a via array is provided in the substrate, the via array is placed across a first region including a region in which the heat-generating component is in contact with the substrate, a second region including a region in which the case is in contact with the substrate, and a third region including a region between the first region and the second region, and a heat-dissipating path from the heat-generating component to the case is formed by the via array.

### Advantageous Effects of Invention

The present disclosure can provide a heat-dissipating structure including a heat-dissipating path enabling efficient heat dissipation.

### BRIEF DESCRIPTION OF DRAWINGS

FIG. 1 is a diagram illustrating an overview of a structure of an electronic device according to a first example embodiment.

FIG. 2 FIG. 2 is a diagram illustrating an example of a heat-dissipating path in the electronic device according to the first example embodiment.

FIG. 3 is a diagram illustrating an overview of a structure of an electronic device for comparison.

FIG. 4 is a diagram illustrating an example of a heat-dissipating path in the electronic device for comparison.

FIG. 5 is a perspective view illustrating a specific example of the shape of a case in the electronic device according to the first example embodiment.

FIG. 6 is a perspective view illustrating a specific example of the shape of the case in the electronic device according to the first example embodiment and a specific example of the placement position of a heat-generating component on a substrate.

FIG. 7A is a plan view illustrating a specific example of a first region, a second region, and a third region in the electronic device according to the first example embodiment.

FIG. 7B is a plan view illustrating a specific example of the placement of a via array in the electronic device according to the first example embodiment.

FIG. 8A is a plan view illustrating another specific example of the first region, the second region, and the third region in the electronic device according to the first example embodiment.

FIG. 8B is a plan view illustrating another specific example of the placement of the via array in the electronic device according to the first example embodiment.

### EXAMPLE EMBODIMENT

Example embodiments of the present disclosure will be described in detail below with reference to accompanying drawings.

### First Example Embodiment

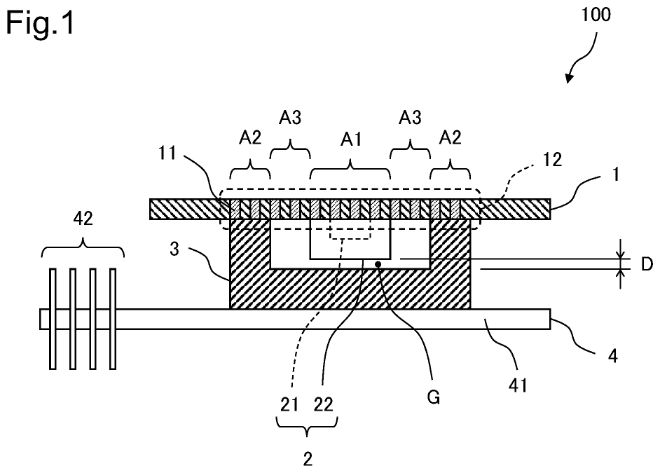

FIG. 1 is a diagram illustrating an overview of a structure of an electronic device according to a first example embodiment. A structure of the electronic device according to the first example embodiment will be described with reference to FIG. 1.

As illustrated in FIG. 1, the electronic device 100 includes a substrate 1. For example, the substrate 1 is composed of a multilayer substrate. A circuit component that may generate heat (hereinafter referred to as a “heat-generating component 2”) is mounted on the substrate 1. The heat-generating component 2 has a structure in which a body unit that may generate heat (hereinafter referred to as a “heat-generating unit 21”) is covered by a package 22.

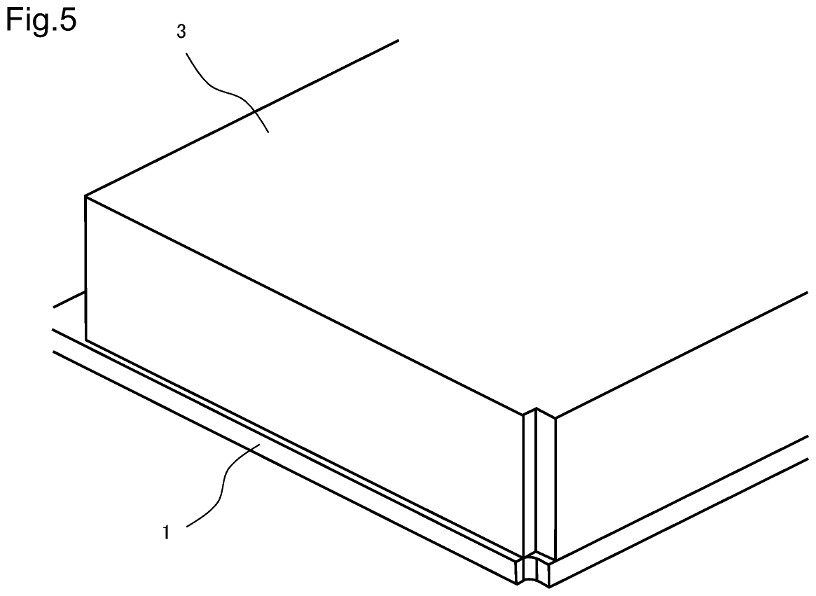

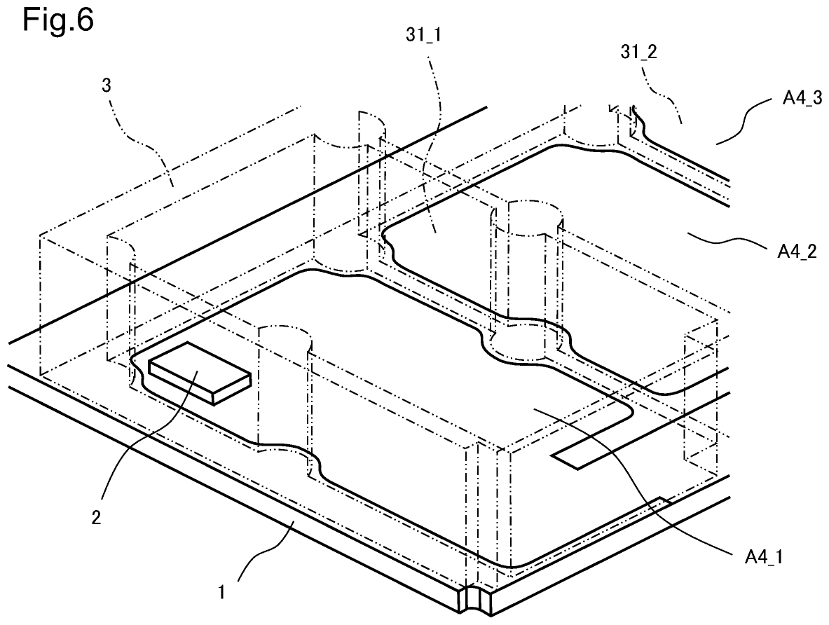

As illustrated in FIG. 1, a case 3 is attached to the substrate 1. The case 3 is made of metal (for example, made of an aluminum alloy). The case 3 is provided in such a way as to at least partially cover the heat-generating component 2. In other words, the case 3 has a shape at least partially covering the heat-generating component 2. Specifically, for example, the shape of the case 3 is almost a lidded-box shape, and the entire heat-generating component 2 is covered by the case 3. A specific example of the shape of the case 3 will be described later with reference to FIG. 5 and FIG. 6.

A gap is formed between each surface of the heat-generating component 2 and a related surface of the case 3 in a state of the heat-generating component 2 being covered by the case 3. In other words, the case 3 has a size large enough to allow the gaps to be formed. G in the diagram indicates the gap between the top surface of the heat-generating component 2 and the top surface of the case 3. D in the diagram indicates the space between the top surface of the heat-generating component 2 and the top surface of the case 3.

As illustrated in FIG. 1, the electronic device 100 includes a heat-dissipating member 4. For example, the heat-dissipating member 4 uses a so-called “heat pipe.” Specifically, the heat-dissipating member 4 includes an almost plate-shaped (more specifically, almost rectangular-plate-shaped) body unit 41. A heat sink 42 is provided on one side of the body unit 41. The heat sink 42 is cooled by an unillustrated cooling fan. An unillustrated heat pipe is provided along a plate surface of the body unit 41. Such a heat pipe is thermally connected to the heat sink 42. The main portion of the heat-dissipating member 4 is thus composed.

The case 3 is thermally connected to the heat-dissipating member 4. Specifically, for example, the case 3 is thermally connected to the heat-dissipating member 4 by the top surface of the case 3 being in contact with the plate surface of the body unit 41 of the heat-dissipating member 4.

The main portion of the heat-dissipating structure in the electronic device 100 is thus composed. The substrate 1, the heat-generating component 2, and the case 3 are accommodated in an unillustrated enclosure. Further, at least the body unit 41 of the heat-dissipating member 4 is also accommodated in such an enclosure.

A plurality of filled vias 11 are provided in the substrate 1. One filled via out of the plurality of filled vias is given a sign “11” in FIG. 1. As illustrated in FIG. 1, every two filled vias 11 adjacent to each other out of the plurality of filled vias 11 are placed close to each other. In other words, the plurality of filled vias 11 are placed in a concentrated manner. A via array 12 is composed of such a plurality of filled vias 11 placed in a concentrated manner.

When the substrate 1 is composed of a multilayer substrate, each filled via 11 penetrates a plurality of layers in such a multilayer substrate. Specifically, for example, each filled via 11 penetrates every layer inside such a multilayer substrate. Each filled via 11 is filled with metal (such as copper).

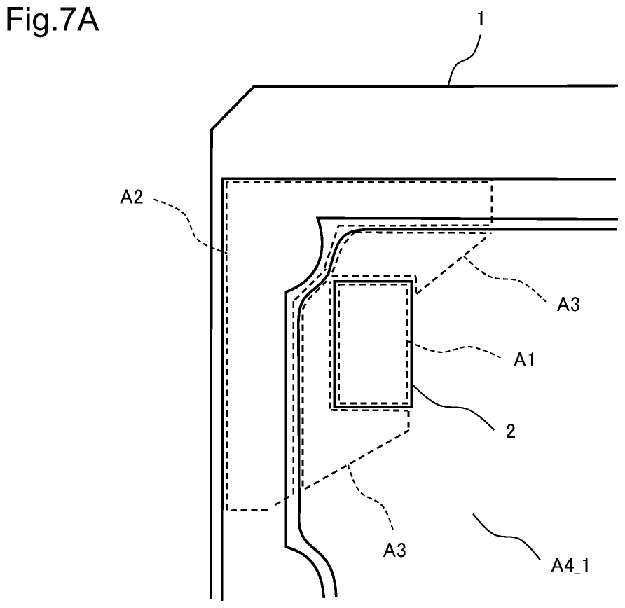

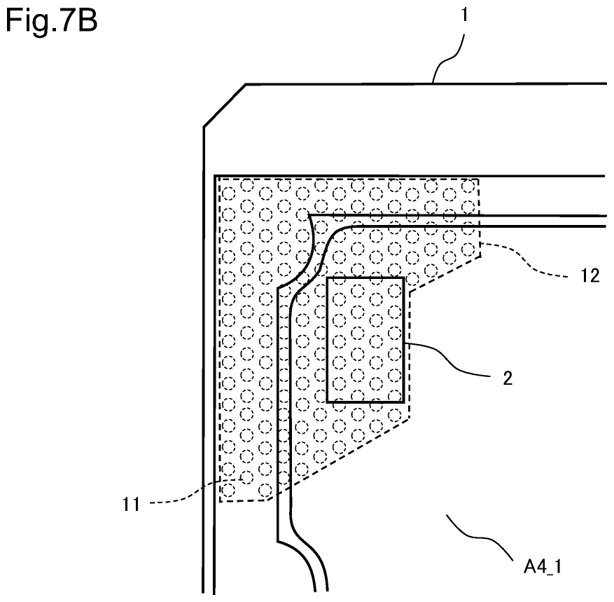

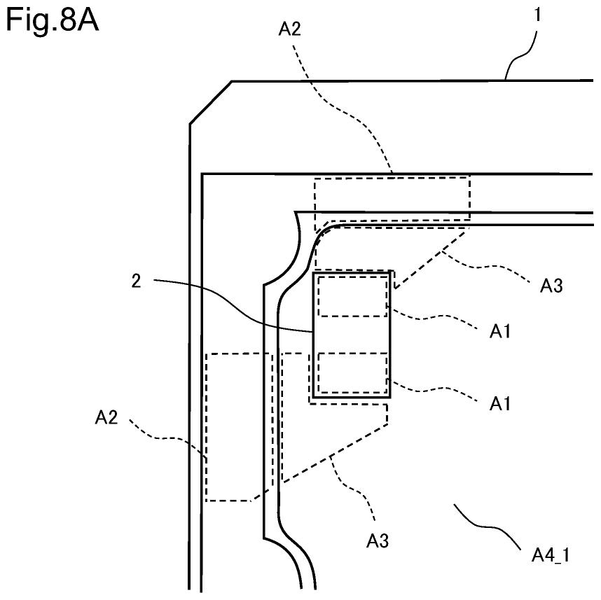

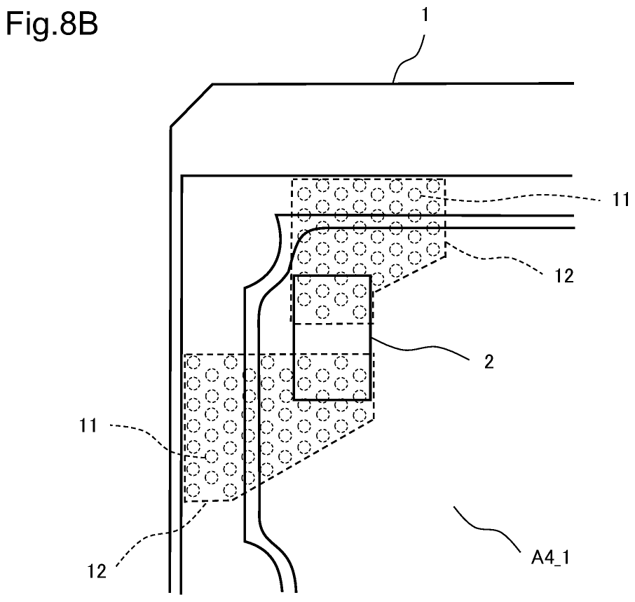

As described above, the heat-generating component 2 is mounted on the substrate 1. Therefore, a region in which the heat-generating component 2 is in contact with the substrate 1 exists on the substrate 1. A predetermined region including at least part of such a region is hereinafter referred to as a “first region.” A1 in the diagram indicates an example of the first region. A specific example of the first region A1 will be described later with reference to FIG. 7A or FIG. 8A.

As described above, the case 3 is attached to the substrate 1. Therefore, a region in which the case 3 is in contact with the substrate 1 exists on the substrate 1. A predetermined region including at least part of such a region is hereinafter referred to as a “second region.” A2 in the diagram indicates an example of the second region. A specific example of the second region A2 will be described later with reference to FIG. 7A or FIG. 8A.

As described above, a gap is formed between each surface of the heat-generating component 2 and a related surface of the case 3. Therefore, a region between the first region A1 and the second region A2 exists on the substrate 1. A predetermined region including at least part of such a region is hereinafter referred to as a “third region.”. A3 in the diagram indicates an example of the third region. A specific example of the third region A3 will be described later with reference to FIG. 7A or FIG. 8A.

As illustrated in FIG. 1, the via array 12 is placed across the first region A1, the second region A2, and the third region A3. In other words, the plurality of filled vias 11 are consecutively placed across the first region A1, the second region A2, and the third region A3. Thus, the heat-generating component 2 is thermally connected to the case 3 through the via array 12. In other words, a heat-dissipating path from the heat-generating component 2 to the case 3 is formed by the via array 12. A specific example of the placement of the via array 12 in the substrate 1 will be described later with reference to FIG. 7B or FIG. 8B.

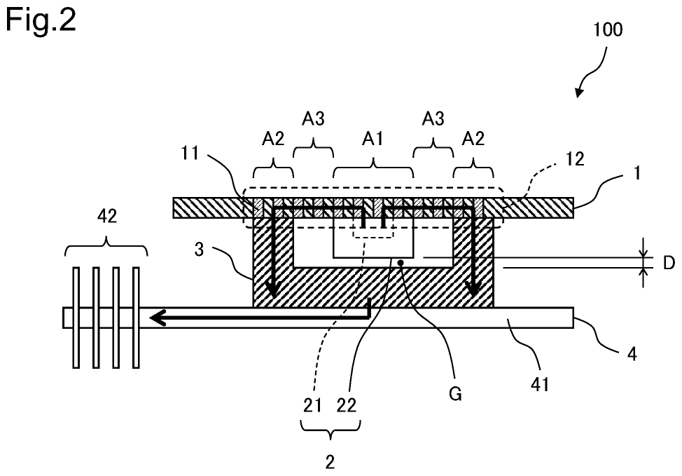

Next, the heat-dissipating path in the electronic device 100 will be described with reference to FIG. 2.

As illustrated in FIG. 2, heat generated by the heat-generating component 2 is transferred to the case 3 through the via array 12. The heat transferred to the case 3 is transferred to the body unit 41 of the heat-dissipating member 4 through a contact surface of the case 3 and the body unit 41. The heat transferred to the body unit 41 is transferred to the heat sink 42 by an unillustrated heat pipe. The heat sink 42 is cooled by an unillustrated fan. Thus, dissipation of heat generated by the heat-generating component 2 is achieved. Arrows in FIG. 2 indicate an example of such as heat-dissipating path.

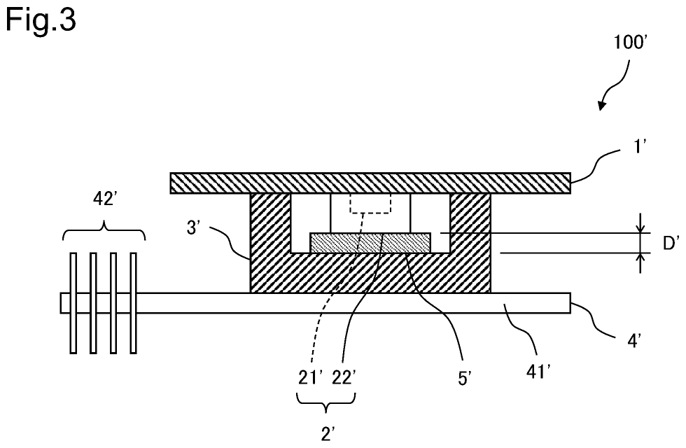

Next, an electronic device 100′ for comparison with the electronic device 100 will be described with reference to FIG. 3.

As illustrated in FIG. 3, the electronic device 100′ includes a substrate 1′, a heat-generating component 2′, a case 3′, and a heat-dissipating member 4′. The substrate 1′, the heat-generating component 2′, the case 3′, and the heat-dissipating member 4′ are similar to the substrate 1, the heat-generating component 2, the case 3, and the heat-dissipating member 4 in the electronic device 100, respectively. Specifically, a heat-generating unit 21′ and a package 22′ in the heat-generating component 2′ are similar to the heat-generating unit 21 and the package 22 in the heat-generating component 2, respectively. Further, a body unit 41′ and a heat sink 42′ in the heat-dissipating member 4′ are similar to the body unit 41 and the heat sink 42 in the heat-dissipating member 4, respectively.

However, a via array corresponding to the via array 12 is not provided in the substrate 1′ in the electronic device 100′. On the other hand, a heat-dissipating sheet 5′ is provided between the top surface of the heat-generating component 2′ and the top surface of the case 3′ in the electronic device 100′. For example, the heat-dissipating sheet 5′ is affixed to the package 22′ of the heat-generating component 2′. The heat-generating component 2′ is thermally connected to the case 3′ through the heat-dissipating sheet 5′. In other words, a heat-dissipating path from the heat-generating component 2′ to the case 3′ is formed by the heat-dissipating sheet 5′. D′ in the diagram indicates the space between the top surface of the heat-generating component 2′ and the top surface of the case 3′. The space D′ is set to a value based on the thickness of the heat-dissipating sheet 5′.

The main portion of the heat-dissipating structure in the electronic device 100′ is thus composed. The substrate 1′, the heat-generating component 2′, the case 3′, and the heat-dissipating sheet 5′ are accommodated in an unillustrated enclosure. Further, at least the body unit 41′ of the heat-dissipating member 4′ is also accommodated in such an enclosure.

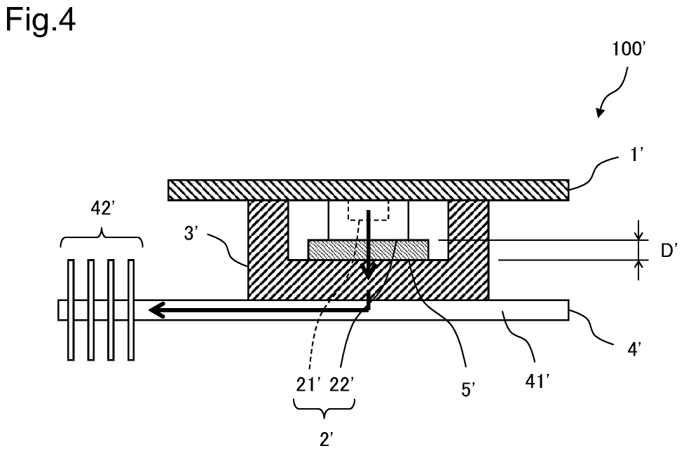

Next, the heat-dissipating path in the electronic device 100′ will be described with reference to FIG. 4.

As illustrated in FIG. 4, heat generated by the heat-generating component 2′ is transferred to the case 3′ through the heat-dissipating sheet 5′. The heat transferred to the case 3′ is transferred to the body unit 41′ of the heat-dissipating member 4′ through a contact surface of the case 3′ and the body unit 41′. The heat transferred to the body unit 41′ is transferred to the heat sink 42′ by an unillustrated heat pipe. The heat sink 42′ is cooled by an unillustrated fan. Thus, dissipation of heat generated by the heat-generating component 2′ is achieved. Arrows in FIG. 4 indicate an example of such a heat-dissipating path.

Next, an issue of the electronic device 100′ will be described. Further, an effect of the electronic device 100 will be described.

As described above, thermal connection between the heat-generating component 2′ and the case 3′ in the electronic device 100′ is performed by the heat-dissipating sheet 5′. Therefore, there is an issue that such a heat-dissipating structure cannot be employed when the heat-dissipating sheet 5′ cannot be provided due to some cause (such as mechanical interference with a material of the package 22 or another component). Further, there is an issue that the number of components increases due to provision of the heat-dissipating sheet 5′. Further, there is an issue that reduction in the thickness of the electronic device 100′ is difficult due to the space D′ not being able to be set to a value less than the thickness of the heat-dissipating sheet 5′.

On the other hand, thermal connection between the heat-generating component 2 and the case 3 in the electronic device 100 is performed by the via array 12 in the substrate 1. Thus, the need for a heat-dissipating sheet corresponding to the heat-dissipating sheet 5′ can be eliminated. Thus, the number of components can be reduced compared with the electronic device 100′. Further, the space D can be set to a value less than the thickness of the heat-dissipating sheet 5′. In other words, the space D can be set to a value less than the space D′. Therefore, reduction in the thickness of the electronic device 100 can be achieved compared with the electronic device 100′.

Next, the issue of the technology described in PTL 1 will be described. Further, another effect of the electronic device 100 will be described.

As described above, the surface heat transfer body and the inner-layer heat transfer body are included in the heat-dissipating path from the semiconductor module to the enclosure component in the technology described in PTL 1. The heat transfer bodies are respectively provided in the layers in the multilayer substrate and are thinly shaped. It is difficult to increase the cross-sectional area of the heat-dissipating path particularly in the stacking direction in the multilayer substrate due to such thinly shaped heat transfer bodies being included in the heat-dissipating path. As a result, there is an issue that achievement of efficient heat dissipation is difficult.

On the other hand, the heat-dissipating path from the heat-generating component 2 to the case 3 is formed by the via array 12 placed across first region A1, the second region A2, and the third region A3 in the electronic device 100. Thus, the cross-sectional area of such a heat-dissipating path can be increased particularly in the thickness direction of the substrate 1 compared with the case of using thinly shaped heat transfer bodies respectively provided in the layers in the multilayer substrate. As a result, more efficient heat dissipation can be achieved compared with the case of using the structure described in PTL 1.

Next, a specific example of the shape of the case 3 will be described with reference to FIG. 5 and FIG. 6. Further, a specific example of the placement position of the heat-generating component 2 on the substrate 1 will be described.

In the example illustrated in FIG. 5 and FIG. 6, the external shape of the case 3 is almost rectangular parallelepipedic. A plurality of regions on which circuit components can be mounted (hereinafter referred to as “mounting regions A4_1 to A4_3”) are provided on the plate surface of the substrate 1. In the example illustrated in FIG. 5 and FIG. 6, wall-shaped partition units 31_1 and 31_2 placed in such a way as to demarcate mounting regions A4 adjacent to each other are formed inside the case 3. Further, in the example illustrated in FIG. 5 and FIG. 6, the heat-generating component 2 is placed at a position close to a corner of the mounting region A4_1.

Next, a specific example of the first region A1, the second region A2, and the third region A3 will be described with reference to FIG. 7A and FIG. 7B. Further, a specific example of the placement of the via array 12 will be described.

The heat-generating component 2 is placed at a position close to a corner of the mounting region A4_1 in the example illustrated in FIG. 7A and FIG. 7B. For example, the first region A1, the second region A2, and the third region A3 in the example illustrated in FIG. 7A and FIG. 7B are set as follows.

Specifically, first, an entire region in which the heat-generating component 2 is in contact with the substrate 1 is set to the first region A1. Second, a region in an area within a predetermined distance from the heat-generating component 2 in a region in which the case 3 is in contact with the substrate 1 is set to the second region A2. Third, a region between the set first region A1 and the set second region A2 in the mounting region A4_1 is set to the third region A3. Note that a region in the mounting region A4_1 in which a filled via 11 cannot be provided due to unillustrated wiring or the like is excluded from the third region A3.

FIG. 7B illustrates an example of a via array 12 related to the first region A1, the second region A2, and the third region A3 illustrated in FIG. 7A. As illustrated in FIG. 7A and FIG. 7B, the via array 12 is placed across the first region A1, the second region A2, and the third region A3. In other words, a plurality of filled vias 11 are consecutively placed across the first region A1, the second region A2, and the third region A3. Thus, a heat-dissipating path from the heat-generating component 2 to the case 3 is formed.

Next, another specific example of the first region A1, the second region A2, and the third region A3 will be described with reference to FIG. 8A and FIG. 8B. Further, another specific example of the placement of the via array 12 will be described.

The via array 12 is composed of one group in the example illustrated in FIG. 7A and FIG. 7B. On the other hand, the via array 12 may be divided into a plurality of groups. Specifically, for example, the via array 12 may be divided into two groups as illustrated in FIG. 8A and FIG. 8B.

Specifically, for example, the first region A1, the second region A2, and the third region A3 in the example illustrated in FIG. 8A and FIG. 8B are set as follows.

First, regions related to both ends of the rectangular heat-generating component 2 excluding the central portion in a region in which the heat-generating component 2 is in contact with the substrate 1 is set to the first regions A1. Thus, two first regions A1 separated from each other are set as illustrated in FIG. 8A.

Second, a region in an area within a predetermined distance from the heat-generating component 2 in a region in which the case 3 is in contact with the substrate 1 is set as the second region A2. Note that a region close to a corner of the substrate 1 in the region in which the case 3 is in contact with the substrate 1 is excluded from the second region A2. Thus, two second regions A2 separated from each other are set as illustrated in FIG. 8A.

Third, a region between each first region A1 and a related second region A2 in the mounting region A4_1 is set to the third region A3. Thus, two third regions A3 separated from each other are set as illustrated in FIG. 8A. Note that a region in the mounting region A4_1 in which a filled via 11 cannot be provided due to unillustrated wiring or the like is excluded from the third region A3.

FIG. 8B illustrates an example of a via array 12 related to the first region A1, the second region A2, and the third region A3 illustrated in FIG. 8A. The via array 12 is divided into two groups as illustrated in FIG. 8B. As illustrated in FIG. 8A and FIG. 8B, each group is placed across the first region A1, the second region A2, and the third region A3. Thus, two heat-dissipating paths from the heat-generating component 2 to the case 3 are formed.

Next, a modified example of the electronic device 100 will be described.

The shape of the case 3 has only to be a shape at least partially covering the heat-generating component 2. In other words, the shape of the case 3 is not limited to an almost lidded-box shape. Further, the shape of the case 3 is not limited to the specific example illustrated in FIG. 5 and FIG. 6. For example, the shape of the case 3 may be a shape with an opening (such as an almost tubular shape).

The first region A1, the second region A2, and the third region A3 are not limited to the specific example illustrated in FIG. 7A or FIG. 8A. In other words, the placement of the via array 12 in the substrate 1 is not limited to the specific example illustrated in FIG. 7B or FIG. 8B. The first region A1, the second region A2, and the third region A3 have only to be set to regions consecutively placed in such a way that a heat-dissipating path from the heat-generating component 2 to the case 3 is formed by the via array 12.

The placement position of the heat-generating component 2 on the substrate 1 is not limited to the specific example illustrated in FIG. 6. For example, when the case 3 with a shape illustrated in FIG. 5 and FIG. 6 is used, the heat-generating component 2 may be placed in the central portion of the mounting region A4_1. However, in this case, the length of a heat-dissipating path inside the substrate 1 (that is, the length of a heat-dissipating path by the via array 12) can be shortened by placing the heat-generating component 2 at a corner of the mounting region A4_1. Thus, more efficient heat dissipation can be achieved.

The heat-dissipating member 4 is not limited to a heat-dissipating member using a heat pipe. The heat-dissipating member 4 has only to be thermally connected to the case 3.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

The whole or part of the example embodiments disclosed above may also be described as, but not limited to, the following Supplementary Notes.

### [Supplementary Notes]

### [Supplementary Note 1]

A heat-dissipating structure for an electronic device including:
a substrate;
a heat-generating component mounted on the substrate;
a case being attached to the substrate and having a shape at least partially covering the heat-generating component; and
a heat-dissipating member thermally connected to the case, wherein
a via array is provided in the substrate,
the via array is placed across a first region including a region in which the heat-generating component is in contact with the substrate, a second region including a region in which the case is in contact with the substrate, and a third region including a region between the first region and the second region, and
a heat-dissipating path from the heat-generating component to the case is formed by the via array.

### [Supplementary Note 2]

The heat-dissipating structure according to Supplementary Note 1, wherein
the substrate is a multilayer substrate, and
each filled via included in the via array penetrates a plurality of layers in the multilayer substrate.

### [Supplementary Note 3]

The heat-dissipating structure according to Supplementary Note 2, wherein
the each filled via penetrates every layer inside the multilayer substrate.

### [Supplementary Note 4]

The heat-dissipating structure according to any one of Supplementary Notes 1 to 3, wherein
the case has a shape covering the entire heat-generating component.

### [Supplementary Note 5]

The heat-dissipating structure according to any one of Supplementary Notes 1 to 4, wherein
the heat-dissipating member uses a heat pipe.

This application is based upon and claims the benefit of priority from Japanese patent application No. 2021-044791, filed on Mar. 18, 2021, the disclosure of which is incorporated herein in its entirety by reference.

### REFERENCE SIGNS LIST

1 Substrate
2 Heat-generating component
3 Case
4 Heat-dissipating member
11 Filled via
12 Via array
21 Heat-generating unit
22 Package
31_1 Partition unit
31_2 Partition unit
41 Body unit
42 Heat sink
100 Electronic device

What is claimed is:

1. A heat-dissipating structure for an electronic device comprising:
a substrate;
a heat-generating component mounted on the substrate;
a case being attached to the substrate and having a shape at least partially covering the heat-generating component; and
a heat-dissipating member thermally connected to the case, wherein
a via array is provided in the substrate,
the via array is placed across a first region including a region in which the heat-generating component is in contact with the substrate, a second region including a region in which the case is in contact with the substrate, and a third region including a region between the first region and the second region, and
a heat-dissipating path from the heat-generating component to the case is formed by the via array.

2. The heat-dissipating structure according to claim 1, wherein
the substrate is a multilayer substrate, and
each filled via included in the via array penetrates a plurality of layers in the multilayer substrate.

3. The heat-dissipating structure according to claim 2, wherein
the each filled via penetrates every layer inside the multilayer substrate.

4. The heat-dissipating structure according to claim 1, wherein
the case has a shape covering the entire heat-generating component.

5. The heat-dissipating structure according to claim 1, wherein
the heat-dissipating member uses a heat pipe.
